(19) United States
(12) Patent Application Publication
(10) Pub. No.: US 2009/0066346 A1
(43) Pub. Date: Mar. 12, 2009

(54) DETECTION CIRCUIT DEVICE AND METHOD FOR DETECTING THE PRESENCE OF AN OBJECT IN THE VICINITY OF A MOTOR VEHICLE

(75) Inventor: Claus Kaltner, Bergkirchen (DE)

Correspondence Address: K.F. ROSS P.C., 5683 RIVERDALE AVENUE, SUITE 203 BOX 900, BRONX, NY, 10471-0900, US

(73) Assignee: IDENT TECHNOLOGY AG, Wessling (DE)

(21) Appl. No.: 12/161,056

(22) PCT Filed: Dec. 18, 2006
(86) PCT No.: PCT/EP2006/012194

§ 371 Date: Jul. 16, 2008

(30) Foreign Application Priority Data
Dec. 16, 2005 (DE) 10 2005 060 778.0

(51) Int. Cl. G01R 27/26

(52) U.S. Cl. 324/681

(57) ABSTRACT

The invention relates to a circuit device and a method for detecting the presence of an object in the vicinity of a motor vehicle. The aim of the invention is to provide solutions which allow monitoring the vicinity of a motor vehicle with regard to the presence of an object. In particular, the aim of the invention is to provide solutions which allow detecting the approach of human body parts to danger-relevant structures, such as for example soft top devices, window openings, door openings and trunk lids, and taking the appropriate safety measures. According to the invention, this problem is solved by a motor vehicle that comprises a detection circuit with a first electrode system, a second electrode system and an alternative current generator for generating a potential difference between the two electrode systems, the first electrode system being arranged in the lower region of the vehicle for inputting the shift current events in the region supporting the vehicle. The detection circuit further comprises an evaluation device by means of which a feedback of the shift current events in the second electrode system is determined via the object to be detected.

The invention relates to a circuit and a method for detecting the presence of an object in the vicinity of a motor vehicle.

A sensor system is known from DE 102 48 761 [U.S. Pat. No. 7,323,885] that allows jamming situations to be detected by means of capacitive interactions.

A jam-sensing system is known from EP 1 154 110 [U.S. Pat. No. 6,337,549], having a profiled seal having an electrode extending therein. When an object, in particular a human limb, approaches this electrode a change in capacitance occurs in a capacitor system including the electrode. This change in capacitance may be detected and evaluated by use of circuitry.

Additional background information concerning the physical effects applicable in the present case, as well as circuits implemented heretofore that are based on these effects, is described in WO 2004/078536 and DE 696 23 115 [U.S. Pat. No. 5,914,701].

The object of the present invention is to provide solutions that allow the vicinity of a motor vehicle to be monitored for the presence of an object. A particular object of the invention is to provide solutions that enable the approach of human limbs toward hazardous structures, such as cabriolet roofs, window openings, door openings, and trunk lids, for example, to be detected and the appropriate safety measures to be taken.

This object is attained according to the invention by means of a motor vehicle having:
a detection circuit comprising a
first electrode,
a second electrode, and
an alternating-current generator for generating a difference in potential between the two electrodes,

the first electrode being mounted on the underside of the vehicle for forming an a-c field in a region underneath the vehicle, and the detection circuit including an evaluating means connected to the second electrode for detecting changes in the a-c field to caused by the object to be detected.

In this manner it is advantageously possible to actively form an a-c field in a region underneath the vehicle so that the object to be detected, in particular a user, functions as a field bridge by means of which feedback of the field to a detection region occurs. Thus, the detection of the presence or intrusion of an object into an observation zone is no longer based solely on changes in the dielectric characteristics of the observation zone, but, rather, is achieved by recording a signal that is actively generated and returned via the object to be detected.

The displacement current may be induced in the base region of the vehicle by supporting a conductive structure directly on the vehicle, in particular a cable on the underside. This design allows a high degree of efficiency.

As an alternative or in combination with this measure, the first electrode may also be formed by structures mounted on the underside of the vehicle. The first electrode may be designed as a plate provided underneath the vehicle. The first electrode may also be formed by the vehicle body itself.

The second electrode is preferably located in the region of the hazardous structures. In particular, it may be extend in the form of a wire or film in the region of the potential pinching edge. The second electrode may also be provided at a location that is likewise subject to approach of an object when a hazardous condition is present.

The second electrode may also be located in the side panel region of the motor vehicle. This allows approaches to the side of the vehicle to be detected. When an approach is detected, recordings, for example images, may be taken of the detected object. This allows damage to the vehicle to be detected and documented.

The second electrode may be divided into multiple detection segments. These detection segments may be queried in sequence, or they may be designed so that each relays information relevant to the respective detection site.

The second electrode may also be designed using other measures in such a way that signals that are relevant to the detection site may be obtained via the second electrode.

The second electrode may also have electrode sections that are not used, or are not used solely, for detecting hazardous approach situations, but that also use signals for controlling other processes, in particular keyless access.

By means of the ground electrode it is also possible to transmit data detected by a user-side electronic key system carried by the user, by means of an electric field. By use of this key system, a signal according to a data set may be transmitted to the user. This signal may be detected by the second electrode.

By use of the above-mentioned design it is possible to recognize whether the vehicle is being approached by an authorized or unauthorized person. Subsequent circuit operations may be coordinated based on this recognition.

As an alternative to an electrical field underneath the vehicle, or also in combination with this measure, by use of field-generating electrodes elsewhere in the side region of the vehicle it is also possible to form an a-c field whose feedback via human limbs may be recorded at a detection site.

Further particulars and details of the invention are described in the following with reference to the drawings, in which:

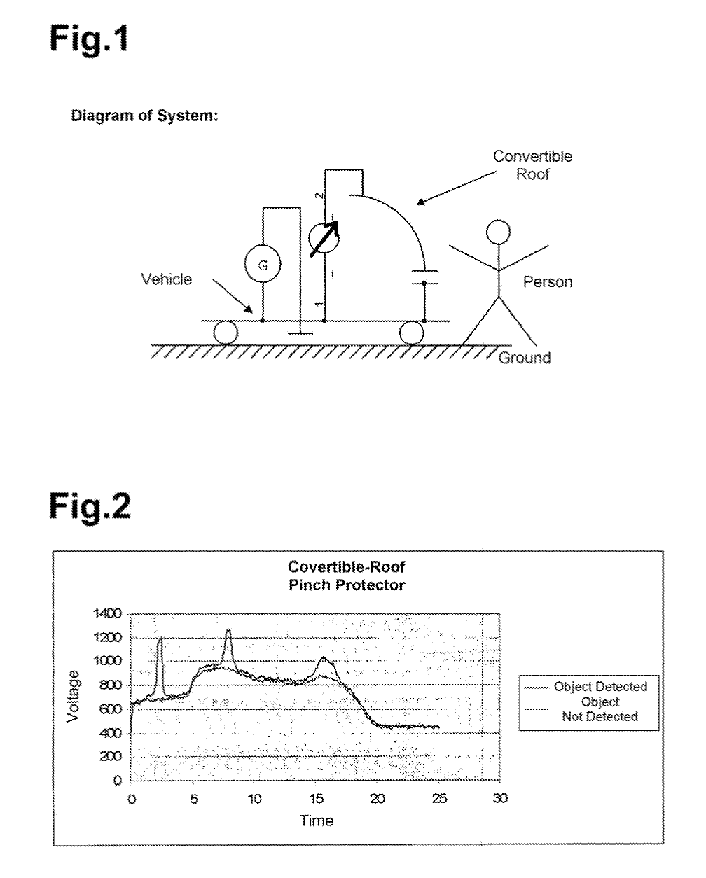

FIG. 1 is a schematic diagram illustrating the inventive concept; and

FIG. 2 is a chart showing the signal when a convertible soft-top roof is closed.

The system illustrated in FIG. 1 comprises a transmitter for forming an a-c field underneath a vehicle, and a receiver.

a) Transmitter

An alternating-current generator is connected by its ground cable to the body of a vehicle. The other cable is connected to an electrode that is insulated from the vehicle body and that underneath it and creates with the ground a field. The generator generates a high-voltage alternating-current having a relatively low frequency.

b) Receiver

The metal frame elements of the convertible soft-top roof or electrodes extending therein are electrically insulated from the vehicle body. The alternating-current field formed between the metal frame elements of the convertible roof and the body is thus detected.

Observed Effect:

When a person approaches the closed cabriolet roof, the field voltage is increased. However, if the person touches the body, the field voltage drops. The person acts as a feedback medium via which the field formed underneath the vehicle may be detected in the region of the second electrode.

Possible Applications:

Antijam protection—the approach-detection system also functions during the actuation process for the convertible roof. Thus, the presence of the limbs of the person in the moving region of the convertible roof may be detected. In this manner antijam protection may be achieved.

Example: Cabriolet Soft-Top Roof

In the antijam protection for a convertible soft-top roof, the characteristic curve of the actuation process is also superimposed by the approach of the person, which may be compensated for by software. FIG. 2 shows the measured alternating-current, both with and without an approach by the person toward the convertible roof.

Furthermore, the closing process for the windows and the closing of the convertible roof cover may be protected.

Protection from vandalism—for example, an alarm and/or photograph (via a camera in the outside mirror, for example) in the event of damage to paint, in particular parking damage from doors of neighboring vehicles.

Keyless access—the convertible is not used, or is not used solely, as a receiving electrode; rather, an electrode is provided in the door handle which permits recognition of whether a person is approaching the door handle with the intent of opening the door.

The following advantages are realized compared to other systems that operate in a capacitive manner:
The system is largely independent of environmental influences such as rain, wind, snow, vibrations, etc.
The system is easy to install or retrofit, since the entire surroundings of the automobile may be monitored by only one transmitter and one receiver. In addition, closing of the convertible roof cover and closing of the windows are protected without having to install additional electrodes.
The system has versatile uses (see possible applications)

1. A motor vehicle having:
a detection circuit comprising
a first electrode,
a second electrode, and
an alternating-current generator for generating a difference in potential between the two electrodes,
the first electrode being underneath the vehicle for forming an a-c field in a region underneath the vehicle, and the detection circuit including an evaluating means by means of which feedback of the a-c field into the second electrode is determined via the object to be detected.

2. The motor vehicle according to claim 1 wherein the first electrode is supported underneath the vehicle.

3. The motor vehicle according to claim 1 wherein the first electrode is formed by structures mounted on the vehicle and facing downward.

4. The motor vehicle according to claim 1 wherein the first electrode is designed as a plate structure provided underneath the vehicle.

5. The motor vehicle according to claim 1 that wherein the first electrode is formed by the vehicle body.

6. The motor vehicle according to at least one of claims 1 through 5 wherein the second electrode is located near hazardous structures.

7. The motor vehicle according to at least one of claims 1 through 6 wherein the second electrode is located in the side panel region of the motor vehicle.

8. The motor vehicle according to at least one of claims 1 through 7 wherein the second electrode is divided into multiple detection segments.

9. The motor vehicle according to at least one of claims 1 through 8 wherein the second electrode is designed in such a way that signals that are relevant to the detection site may be obtained via the second electrode.

10. A method for monitoring at least one zone in the vicinity of a motor vehicle, in which a high-frequency a-c field is formed underneath the vehicle by means of an electrode assembly, and in which feedback of the displacement current event by means of the second electrode to the zone being observed is established via the object to be detected.
